(19) United States
(12) Patent Application Publication
(10) Pub. No.: US 2015/0014028 A1
(43) Pub. Date: Jan. 15, 2015

(54) INSULATING FILM FOR PRINTED CIRCUIT BOARD AND PRODUCT MANUFACTURED BY USING THE SAME

(71) Applicant: SAMSUNG ELECTRO-MECHANICS CO., LTD., Suwon (KR)

(72) Inventors: Hwa Young Lee, Suwon (KR); Ho Hyung Ham, Suwon (KR); Jun Ho Bae, Suwon (KR); Ki Seok Kim, Suwon (KR); Eui Jung Jung, Suwon (KR); Ji Hye Shim, Suwon (KR)

(73) Assignee: SAMSUNG ELECTRO-MECHANICS CO., LTD., Suwon (KR)

(21) Appl. No.: 14/094,588

(22) Filed: Dec. 2, 2013

(30) Foreign Application Priority Data
Jul. 9, 2013 (KR) 10-2013-0080517

(51) Int. Cl. H05K 1/02; B32B 15/085

(52) U.S. Cl. CPC H05K 1/0271; B32B 15/085
USPC 174/257; 428/523; 428/413; 428/336; 428/461

(57) ABSTRACT

Disclosed herein are an insulating film for a printed circuit board, a resin coated copper (RCC), a flexible copper clad laminate (FCCL), and a printed circuit board manufactured by using the same. More specifically, the RCC, the FCCL, and the printed circuit board manufactured by using the insulating film for the printed circuit board according to the preferred embodiment of the present invention, the insulating film including an insulating layer, and a primer layer formed on one surface of the insulating layer and including a benzocyclobutene (BCB)-based resin, may have a low coefficient of thermal expansion and high peel strength.

### CROSS REFERENCE TO RELATED APPLICATION

This application claims the benefit of Korean Patent Application No. 10-2013-0080517, filed on Jul. 9, 2013, entitled “Insulating Film for Printed Circuit Board And Product Manufactured by Using the Same”, which is hereby incorporated by reference in its entirety into this application.

### BACKGROUND OF THE INVENTION

1. Technical Field

The present invention relates to an insulating film for a printed circuit board and a product manufactured by using the same.

2. Description of the Related Art

As an electronic device has a small size and a high performance, a multilayer printed circuit board has been demanded to have a high density, a high function, a small size, and a thin thickness. Accordingly, a printed circuit board mounting various electronic components has been gradually fine-patterned according to meeting demands for the thin film and high integration.

In particular, in order to develop wire to be miniaturized and have high density, a process in which an insulating film without a glass cloth is built-up to form a circuit by a semi-additive process (SAP) or a modified semi-additive process (MSAP) scheme instead of a process for forming the insulating layer of a prepreg type in which the glass cloth is impregnated has increasingly used. In addition, the build-up layer of the multilayer printed circuit board has multilayers.

In addition, thermal, mechanical, and electrical properties in a build-up insulating film replacing the prepreg (PPG) and an insulating layer of the multilayer printed circuit board are also important factors. The insulating layer has been demanded to have a low coefficient of thermal expansion, a high glass transition temperature, and a modulus property in order to minimize warpage generated by a reflow in a mounting process of an electronic device or an electrical device.

Recently, various methods for improving thermal, mechanical, and electrical properties of the insulating layer of the build-up layer which is used in the multilayer printed circuit board used in the electronic device according to the development of the electronic device have been studied. Among the various methods, an inorganic filler is filled in the insulating layer in order to achieve high peel strength, a low dielectric constant, and a low coefficient of thermal expansion, and therefore, a content of the inorganic filler has been gradually increased according to the demand of the printed circuit board. However, the increased content of the inorganic filler may cause defects in a circuit process and deterioration in reliability.

For example, Patent Document 1 discloses a primer layer formed by using an aromatic polyamide-based resin, a thermosetting resin, and a filler particle in order to solve the above-described problems. Here, an epoxy resin, a cyanate resin, benzocyclobutene, or the like, is used as the thermosetting resin.

In the printed circuit board according to the prior art, a circuit layer is formed by a plating process, wherein a desmear (roughening plating) process for forming illuminance by etching a surface of the insulating layer using a potassium permanganate solution in order to increase a plating adhesion between the circuit layer and the insulating layer is performed. Here, since an organic matrix portion is selective removed in the desmear process including swelling, etching, and neutralization, in the case in which the content of the inorganic filler is increased in the insulating film, large amounts of inorganic fillers remain on the surface of the insulating layer after the desmear process. The inorganic filler exposed on the surface of the insulating layer decreases the plating adhesion between the insulating layer and the circuit layer, causing defects in the circuit process and deterioration in the reliability.

In other words, according to the recent trend, the filling content of the inorganic filler is increased in the insulating layer, such that it is difficult to achieve the peel strength between the circuit layer and the insulating layer, and in the case in which the filling content of the inorganic filler is decreased in order to achieve the peel strength, the coefficient of thermal expansion of the insulating layer is not sufficiently small.

Therefore, a method for maintaining the thermal expansion property of the insulating layer and securing the plated adhesion is required.

### PRIOR ART DOCUMENT

### Patent Document

Patent Document 1 Korean Patent Laid-Open Publication No. 2012-0021243

### SUMMARY OF THE INVENTION

In the present invention, it is confirmed that an insulating film for a printed circuit board including an insulating film and a primer layer formed on one surface of the insulating layer and including a benzocyclobutene (BCB)-based resin and a product manufactured by using the same have a low coefficient of thermal expansion and high peel strength, thereby completing the present invention.

Therefore, the present invention has been made in an effort to provide the insulating film for the printed circuit board having the low coefficient of thermal expansion and the high peel strength.

In addition, the present invention has been made in an effort to provide a resin coated copper (RCC) or a flexible copper clad laminate (FCCL) manufactured by stacking copper clad layers on one surface or both surfaces of the insulating film.

Further, the present invention has been made in an effort to provide a printed circuit board manufactured by stacking the resin coated coppers (RCCs) or the flexible copper clad laminates (FCCLs) on a substrate having a circuit pattern formed therein.

According to a preferred embodiment of the present invention, there is provided an insulating film for a printed circuit board including: an insulating layer; and a primer layer formed on one surface of the insulating layer and including a benzocyclobutene (BCB)-based resin.

The insulating layer may include a liquid-crystal oligomer, an epoxy resin, and an inorganic filler, and the primer layer may include the benzocyclobutene (BCB)-based resin and the epoxy resin.

The insulating layer may include the liquid-crystal oligomer in an amount of 4 to 30 wt %, the epoxy resin in an amount of 5 to 30 wt %, and the inorganic filler in an amount of 40 to 90 wt %.

The primer layer may include the benzocyclobutene (BCB)-based resin in an amount of 50 to 80 wt % and the epoxy resin in an amount of 20 to 50 wt %.

The primer layer may include the benzocyclobutene (BCB)-based resin in an amount of 60 to 70 wt % and the epoxy resin in an amount of 30 to 40 wt %.

The epoxy resin included in the insulating layer or the primer layer may be at least one selected from a group consisting of a naphthalene-based epoxy resin, a bisphenol A type epoxy resin, a phenol novolak epoxy resin, a cresol novolak epoxy resin, a rubber-modified epoxy resin, a phosphorus-based epoxy resin, and a bisphenol F type epoxy resin.

The inorganic filler may be at least one selected from a group consisting of silica (SiO₂), alumina (Al₂O₃), silicon carbide (SiC), barium sulfate (BaSO₄), talc, clay, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), calcium zirconate (CaZrO₃), and a combination thereof.

The inorganic filler included in the insulating layer may have a concentration gradient in a thickness of the insulating layer, and have a higher concentration distribution in a region distant from the primer layer than in a region adjacent to the primer layer in the insulating layer.

The primer layer may have a thickness in a range of 1 μm to 3 μm.

The insulating layer or the primer layer may further include a curing agent, a curing accelerator, or a combination thereof.

The curing agent may be at least one selected from a group consisting of an amine-based curing agent, an acid anhydride-based curing agent, a polyamine curing agent, a polysulfide curing agent, a phenol novolak type curing agent, a bisphenol A type curing agent, and a dicyandiamide curing agent.

The curing accelerator may be at least one selected from a group consisting of a metal-based curing accelerator, an imidazole-based curing accelerator, and an amine-based curing accelerator.

The primer layer may be formed by directly applying a primer solution on the insulating layer or casting the primer solution on a carrier film and then laminating and transferring the primer solution on the insulating layer.

According to another preferred embodiment of the present invention, there is provided a resin coated copper (RCC) or a flexible copper clad laminate (FCCL) manufactured by stacking and laminating copper clad layers on the primer layer of the insulating film for a printed circuit board as described above.

According to another preferred embodiment of the present invention, there is provided a printed circuit board manufactured by stacking and laminating the resin coated copper (RCC) or the flexible copper clad laminate (FCCL) as described above on a substrate having a circuit pattern formed therein.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of an insulating film for a printed circuit board according to a preferred embodiment of the present invention;

FIG. 2 is a cross-sectional view of an insulating film for a printed circuit board according to another preferred embodiment of the present invention;

FIG. 3 is a cross-sectional view of a resin coated copper (RCC) having an insulating film for a printed circuit board according to another preferred embodiment of the present invention; and

FIG. 4 is a cross-sectional view of a flexible copper clad laminate (FCCL) having the insulating film for the printed circuit board according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the prior art would obscure the gist of the present invention, the description thereof will be omitted.

Hereinafter, preferred embodiments of the present invention will be described in detail with reference to the attached drawings.

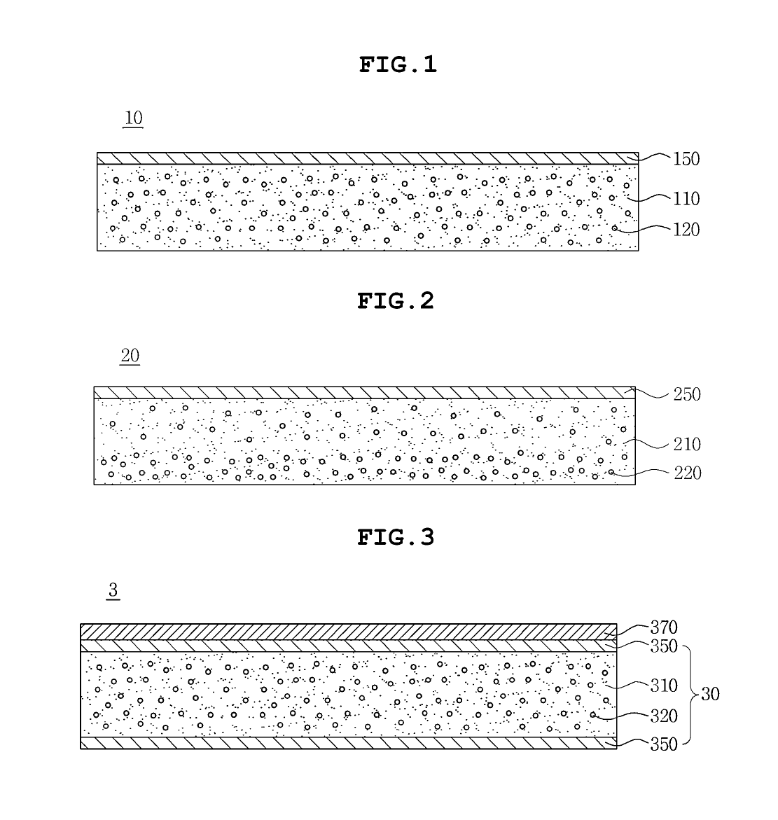

FIG. 1 is a cross-sectional view of an insulating film for a printed circuit board according to a preferred embodiment of the present invention, and FIG. 2 is a cross-sectional view of an insulating film for a printed circuit board according to another preferred embodiment of the present invention.

Referring to FIGS. 1 and 2, the insulating films for the printed circuit board 10 and 20 according to the preferred embodiment of the present invention include insulating layers 110 and 210 including an inorganic filler; and primer layers 150 and 250 formed on one surface of the insulating layers 110 and 210 and including a benzocyclobutene (BCB)-based resin. The primer layers 150 and 250 may contain the benzocyclobutene (BCB)-based resin having significant adhesion with a metal, such that a roughening process, or the like, may not be needed, the convenience of the process may be improved, and a plating adhesion may be stably secured. In addition, a resin coated copper (RCC), a flexible copper clad laminate (FCCL), and a printed circuit board including the insulating films 10 and 20 may be provided.

First, the insulating layers 110 and 210 of the insulating films 10 and 20 for the printed circuit board according to the preferred embodiment of the present invention may include an epoxy resin, and inorganic fillers 120 and 220. In addition, the insulating layers 110 and 210 may further include a liquid-crystal oligomer, or the like, in consideration of thermal, mechanical, and electrical properties.

The epoxy resin used in the insulating layers 110 and 210 may be at least one selected from a group consisting of a naphthalene-based epoxy resin, a bisphenol A type epoxy resin, a phenol novolak epoxy resin, a cresol novolak epoxy resin, a rubber-modified epoxy resin, a phosphorus-based epoxy resin and a bisphenol F type epoxy resin, and the naphthalene-based epoxy resin or the bisphenol A type epoxy resin is preferred.

An amount of epoxy resin used in the insulating layers 110 and 210 in the insulating films 10 and 20 according to the preferred embodiment of the present invention is not particularly limited, but for example, the amount thereof may be 10 to 20 wt % and may be in a range of 5 to 30 wt %. In the case in which the used amount of epoxy resin is less than 5 wt %, peel strength may be deteriorated, and in the case in which the used amount thereof is more than 30 wt %, a coefficient of thermal expansion will be increased. In addition, the insulating layer may include the liquid-crystal oligomer, and/or a filler, for example, an inorganic filler. Here, the liquid-crystal oligomer may be included in an amount of 4 to 30 wt % in order to decrease the coefficient of thermal expansion of the film.

As the inorganic fillers 120 and 220, silica (SiO₂), alumina (Al₂O₃), silicon carbide (SiC), barium sulfate (BaSO₄), talc, clay, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃) may be used alone or two kinds or more may be combined with each other. The inorganic fillers 120 and 220 are not particularly limited, but an average particle diameter thereof is preferably 0.05 to 2 μm, and the same kind or two kinds of inorganic filler may be used.

The amount of inorganic fillers 120 and 220 used in the insulating layers 110 and 120 in the insulating films 10 and 20 according to the preferred embodiment of the present invention is 40 to 90 wt %, preferably 60 to 90 wt %, more preferably 70 to 90 wt %, and most preferably 80 to 90 wt %. In the case in which the used amount of inorganic fillers 120 and 220 is less than 40 wt %, a dielectric property may be decreased and the coefficient of thermal expansion may be increased, and in the case in which the used amount thereof is more than 90 wt %, the peel strength may be deteriorated.

Meanwhile, the insulating films 10 and 20 according to the embodiments of the present invention shown in FIGS. 1 and 2 have different distribution of the inorganic fillers 120 and 220 in to the insulating layers 110 and 210. In the insulating film 10 shown in FIG. 1, the inorganic filler 120 is uniformly distributed in the insulating film 110, meanwhile, in the insulating film 20 shown in FIG. 2, the inorganic filler 220 has a different concentration gradient in a thickness direction of the insulating layer 120.

Referring to FIG. 2, in the case in which the inorganic filler 220 has different concentration gradient in the thickness direction of the insulating layer 210, the inorganic filler 220 may have a higher concentration distribution in a region distant from the primer layer 250 than in a region adjacent to the primer layer 250 in the insulating layer 210. As described above, known methods in the art, for example, two insulating sheets having different concentration of the inorganic fillers are stacked, and the like, are used and the inorganic filler 220 in the insulating layer has the different concentration gradient, such that the coefficient of thermal expansion property and the plating adhesion may be improved.

Primer Layer

The primer layers 150 and 250 of the insulating films 10 and 20 according to the preferred embodiment of the present invention may include a benzocyclobutene-based resin, a thermal curable resin, for example, an epoxy resin, and may be formed on one surface of the insulating layers 110 and 120. Here, the benzocyclobutene-based resin may have low dielectric constant, dissipation factor, coefficient of moisture-absorption, and coefficient of thermal expansion (CTE), and excellent thermal stability and chemical resistance to improve physical properties of the insulating film.

In addition, a curing process is performed at a low temperature, by-products such as water, and the like, are not generated during a process, and planarization is excellent, such that it is easy to manufacture a film, and a microelectronic device having a multilayer structure may be manufactured.

The primer layers 150 and 250 of the insulating films 10 and 20 according to the preferred embodiments of the present invention may have a thickness in a range of 1 μm to 3 μm. In the case in which the general primer layer according to the prior art has a thickness less than 3 μm, the primer layer itself is destroyed by the desmear process, such that the peel strength is deteriorated and it is difficult to achieve a fine circuit. However, the primer layers 150 and 250 of the insulating films 10 and 20 according to the preferred embodiments of the present invention includes the benzocyclobutene-based resin, such that the plating adhesion with the copper clad layer formed on the primer layers 150 and 250 may be improved without performing the desmear process, thereby having a thickness in a range of 1 μm to 3 μm.

In addition, it is preferred that the primer layer includes the benzocyclobutene (BCB)-based resin in an amount of 50 to 80 wt % and the epoxy resin in an amount of 20 to 50 wt %. In the case in which the benzocyclobutene (BCB)-based resin has an amount of 80 wt % or more, the coefficient of thermal expansion property is deteriorated, and in the case in which the benzocyclobutene (BCB)-based resin has an amount less than 50 wt %, the plating adhesion is deteriorated. Therefore, a composition of the primer layer is controlled to improve the plating adhesion with the copper clad layer and the coefficient of thermal expansion property, thereby manufacturing the insulating film for the printed circuit board.

Further, in the primer layers 150 and 250 in the insulating films 10 and 20 according to the preferred embodiments of the present invention, the epoxy resin may be at least one selected from a group consisting of the naphthalene-based epoxy resin, the bisphenol A type epoxy resin, the phenol novolak epoxy resin, the cresol novolak epoxy resin, the rubber-modified epoxy resin, the phosphorus-based epoxy resin and the bisphenol F type epoxy resin, and the naphthalene-based epoxy resin or the bisphenol A type epoxy resin is preferred.

In the preferred embodiment of the present invention, a curing agent, a curing accelerator, or a combination thereof may be selective used in the insulating layers 110 and 210 or the primer layers 150 and 250 in the insulating films 10 and 20 for the printed circuit board.

Any curing agent may be generally used as long as the curing agent includes a reacting group which is capable of reacting with an epoxide ring included in the epoxy resin, but is not particularly limited. More specifically, examples of the curing agent may include an amine-based curing agent, an acid anhydride-based curing agent, a polyamine curing agent, a polysulfide curing agent, a phenol novolak type curing agent, a bisphenol A type curing agent and a dicyandiamide curing agent, and one kind or a combination of two or more kinds of curing agent may be used. The used amount of curing agent may be appropriately selected in a range of 0.1 to 1 part by weight with respect to 100 parts by weight of the insulating layers 110 and 210 or the primer layers 150 and 250 in consideration of a curing rate without deteriorating physical properties.

Examples of the curing accelerator may include a metal-based curing accelerator, an imidazole-based curing accelerator and an amine-based curing accelerator, and one kind or a combination of two or more kinds of a curing accelerator may be used.

Examples of the metal-based curing accelerator may include an organic metal complex or an organic metal salt of a metal such as cobalt, copper, zinc, iron, nickel, manganese, tin, or the like, but the present invention is not specifically limited thereto. Specific examples of the organic metal complex may include organic cobalt complex such as cobalt (II) acetylacetonate, cobalt (III) acetylacetonate, or the like, organic copper complex such as copper (II) acetylacetonate, organic zinc complex such as zinc (II) acetylacetonate, organic iron complex such as iron (III) acetylacetonate, organic nickel complex such as Ni (II) acetylacetonate, organic manganese complex such as manganese (II) acetylacetonate, and the like. Examples of the organic metal salt may include zinc octyl acid, tin octyl acid, zinc naphthenic acid, cobalt naphthenic acid, tin stearic acid, zinc stearic acid, and the like. As the metal-based curing accelerator, cobalt (II) acetylacetonate, cobalt (III) acetylacetonate, zinc (II) acetylacetonate, zinc naphthenic acid, iron (III) acetylacetonate is preferred, and in particular, cobalt (II) acetylacetonate and zinc naphthenic acid is more preferred, in view of curability and a solvent solubility. One kind or a combination of two or more kinds of the metal-based curing accelerator may be used.

Examples of the imidazole-based curing accelerator may include imidazole compounds such as 2-methylimidazole, 2-undecylimidazole, 2-heptadecylimidazole, 1,2-dimethylimidazole, 2-ethyl-4-methylimidazole, 1,2-dimethylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-undecylimidazole, 1-cyanoethyl-2-ethyl-4-methylimidazole, 1-cyanoethyl-2-phenylimidazole, 1-cyanoethyl-2-undecylimidazoliumtrimellitate, 1-cyanoethyl-2-phenylimidazoliumtrimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl4′-methylimidazolyl-(1′)]-ethyl-s-triazine, 2,4-diamino-6-[2′-methylimidazolyl-(1′)]-ethyl-s-triazineisocyanic acid adduct, 2-phenyl-imidazoleisocyanic acid adduct, 2-phenyl-4,5-dihydroxymethylimidazole, 2-phenyl-4-methyl-5-hydroxymethylimidazole, 2,3-dihydroxy-1H-pyroro[1,2-a]benzimidazole, 1-dodecyl-2-methyl-3-benzyl-imidazoliumchloride, 2-methylimidazoline, and 2-phenyl-imidazoline, and an adduct of the imidazole compounds and the epoxy resin, but the present invention is not particularly limited thereto. One kind or a combination of two or more kinds of the imidazole-based curing accelerator may be used.

Examples of the amine-based curing accelerator may include trialkylamine such as triethylamine and tributylamine, and an amine compound such as 4-dimethylaminopyridine, benzyldimethylamine, 2,4,6-tris(dimethylamino-methyl)phenol, 1,8-diazabicyclo(5,4,0)-undecene, but the present invention is not specifically limited thereto. One kind or a combination of two or more kinds of the amine-based curing accelerator may be used.

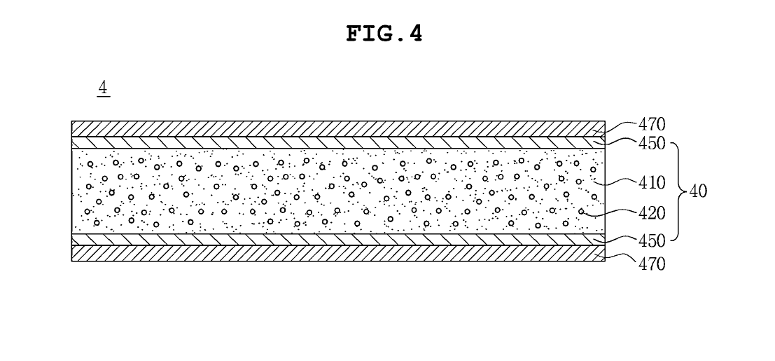

FIG. 3 is a view showing a resin coated copper (RCC) having the insulating film for the printed circuit board according to another preferred embodiment of the present invention, and FIG. 4 is view showing a flexible copper clad laminate (FCCL) having the insulating film for the printed circuit board according to another preferred embodiment of the present invention.

As shown in FIGS. 3 and 4, the insulating films 30 and 40 according to the preferred embodiment of the present invention and the RCC 3 and the FCCL 4 manufactured by using the same are laminated on a copper clad laminate (CCL) used as an inner layer at the time of manufacturing a multilayer printed circuit board and are used in manufacturing the multilayer printed circuit board.

That is, the printed circuit board is largely classified into the insulating layers 310 and 410 and the copper clad layers 370 and 470. In addition, in the printed circuit board, the copper clad layer is formed on at least one surface of the insulating layer, and again the insulating layer is formed on the copper clad layer by using a build-up film, and then the copper clad layer is again formed, thereby configuring continuous build-up layers. The printed circuit board may include a capacitor, a resistor, or other electronic components as needed, and the outermost thereof may be provided with a solder resist layer in order to protect the circuit board. The printed circuit board may be provided with external connection units according to electronic products to be mounted thereon, and sometimes provided with a pad layer. The printed circuit board manufactured by the preferred embodiment of the present invention may have excellent coefficient of thermal expansion property and excellent peel strength between the insulating layer and the copper clad layer.

Hereinafter, the present invention will be described in more detail with reference to the following Examples and Comparative Examples; however, it is not limited thereto.

### EXAMPLE 1

Preparation of Insulating Layer

A liquid-crystal oligomer 6 g containing a hydroxyl group at an end portion thereof was added to N,N′-dimethylacetamide (DMAc) 6 g to prepare a liquid-crystal oligomer solution, and a silica (SiO₂) slurry 102.41 g was added thereto, followed by stirring for 30 minutes. An epoxy resin Araldite MY-721 (Huntsman Corporation) 8 g was added to the reactant, followed by stirring for 1 hour. Then, dicyandiamide (DICY) 0.08 g and azobisbutyronitrile (AIBN) 0.09 g were added to the reactant, followed by additional stirring for 30 minutes. The reactant was applied to a shiny copper clad surface by a doctor blade scheme so as to have a thickness of about 80 μm to manufacture a film, and the film was dried in the oven at 80° C. and 120° C. for 30 minutes, respectively, to be manufactured in a semi-cured (B-stage) state.

Preparation of Primer Layer

N,N′-dimethylacetamide (DMAc) 4 g was added to a benzocyclobutene-based resin 43.64 g containing a carboxylic group at an end portion thereof and dissolved into N,N′-dimethylacetamide (DMAc) and then 4-functional group naphthylene-based epoxy resin (HP-4710, DIC) 3 g was added thereto, followed by stirring for 1 hour. The reactant was applied to a shiny copper clad surface by a doctor blade scheme so as to have a thickness of about 3 μm to manufacture a film, and the film was dried in the oven at 80° C. and 120° C. for 30 minutes, respectively, to be manufactured in a semi-cured (B-stage) state.

Preparation of Insulating Film

Each of the primer layers was stacked on one surface of the insulating layer including the inorganic filler, or was directly transferred on the insulating layer, and a primary reaction was performed by using a vacuum press to manufacture the film in the semi-cured (B-stage) state.

Here, the primer layer may contain the benzocyclobutene-based resin as a main component and cause a reaction as shown in the following Reaction Formula 1 through a photocurable reaction or a curable reaction.

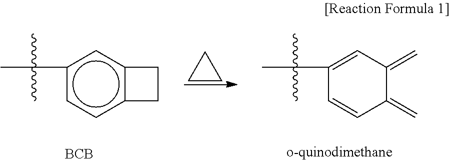

In Reaction Formula 1, the copper clad layer was plated on the primary reacted primer layer by an electroless plating method, and the primer layer was then completely cured by a secondary reaction as shown in the following Reaction Formula 2 (maximum temperature 230° C., maximum pressure 2 MPa).

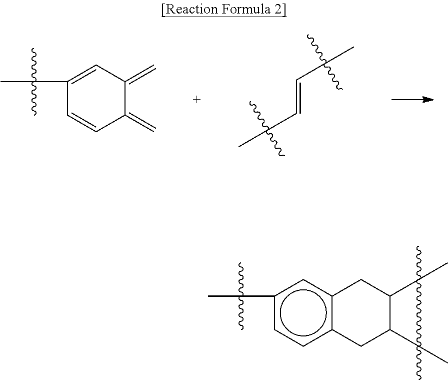

In Reaction Formula 2, the plating adhesion may be improved due to a photocurable or photoreactive benzocyclobutene-based resin having an interconnected network structure by a ring-opening reaction and a diels-Alder reaction of the benzocyclobutene-based resin.

### EXAMPLE 2

A first insulating film including the insulating film having a film thickness of about 40 μm was manufactured according to Example 1, and a second insulating film including the insulating film having a film thickness of about 40 μm, the second insulating film having the silica (SiO₂) slurry 50 g of the insulating layer, was manufactured according to Example 1, thereby stacking the manufactured first and second insulating films to manufacture an insulating film having a different concentration gradient. Here, the primer layer was used as the same as Example 1, and formed on the first insulating film including the inorganic filler at a low concentration. Other experimental conditions except for the above-described conditions were the same as Example 1.

### COMPARATIVE EXAMPLE 1

Acid modified cresolnovolak epoxyacrylate (Japanese Powder, CCR-1591H) 150 g, a bisphenol A type epoxy resin (Momentive, EP631) 64 g, urethane acrylate (Miwon Special Drug, UA105) 18 g, and a photoinitiator (BASF, Irgacure 184D) 3 g were dissolved into methylethylketone 180 g and was used as the primer layer instead of the existing primer layer used in Example 1. After a dispersant (KYOEISHA, G700) 3 g was firstly mixed with the dissolved reactant, the mixed reactant was casted so that the insulating layer has a thickness of 3 μm, and dried in the oven at 80° C. for 10 minutes to manufacture the insulating film. In addition, a desmear process was performed on the primer layer by using manganese peroxide to be roughened, and the copper clad layer was formed on the roughened primer layer. Other experimental conditions except for the above-described conditions were the same as Example 1.

### COMPARATIVE EXAMPLE 2

Acid modified epoxy acrylate cresolnovolak epoxyacrylate (Japanese Powder, CCR-1591H) 150 g, a bisphenol A type epoxy resin (Momentive, EP631) 64 g, urethane acrylate (Miwon special drug, UA105) 18 g, and a photoinitiator (BASF, Irgacure 184D) 3 g were dissolved into methylethylketone 180 g and was used as the primer layer instead of the existing primer layer used in Example 1. After a dispersant (KYOEISHA, G700) 3 g was firstly mixed with the dissolved reactant, the mixed reactant was casted so that the insulating layer has a thickness of 8 μm, and dried in the oven at 80° C. for 10 minutes to manufacture the insulating film. In addition, a desmear process was performed on the primer layer by using manganese peroxide to be roughened, and the copper clad layer was formed on the roughened primer layer. Other experimental conditions except for the above-described conditions were the same as Example 1.

### EXAMPLE 3

Manufacture of Printed Circuit Board

A circuit board having an inner layer in which copper clads are stacked on both surfaces thereof was dried at 120° C. for 30 minutes, a Morton CVA 725 vacuum laminator was used to laminate the insulating film manufactured by Example 1 or Example 2 on both surfaces thereof for 20 seconds under the condition of 90° C. and 2MPa, thereby manufacturing a printed circuit board.

Measurement of Physical Properties

Evaluation on the insulating films manufactured by Examples and Comparative Examples in view of physical properties is shown in the following Table 1. In measurement and evaluation of a coefficient of thermal expansion, the films were measured in a temperature range of 50° C. to 100° C. by using a thermo mechanical analysis (TMA), and were thermo mechanical-analyzed by using a tension weight acceleration. A sample was mounted on TMA, and was measured under the measurement condition having a rising temperature rate of 5° C./mins. An average line thermal expansion rate (ppm) of coefficients of thermal expansion (α1, Tg or less) at from 50° C. up to 100° C. was calculated in the measurement of coefficient of thermal expansion (CTE). In measurement and evaluation of a peel strength, the peel strength between the copper clad layer and the insulating layer was measured by using a universal testing machine (UTM).

TABLE 1

| | Coefficient of Thermal Expansion | Plated Adhesion |
|---|---|---|
| | (CTE) | (peel strength) |
| | (ppm/° C.) | (kgf/cm) |
| Example 1 | 17.5 | 0.54 |
| Example 2 | 16.0 | 0.58 |
| Comparative | 18.2 | Cannot be Measured |
| Example 1 | | |
| Comparative | 18.2 | 0.51 |
| Example 2 | | |

As shown in Table 1 above, the insulating films manufactured by Examples 1 and 2 have excellent coefficient of thermal expansion and peel strength as compared to those manufactured by Comparative Examples 1 and 2, and in particular, the insulating film manufactured by Example 2 shows the best results. The reason is that in the insulating film manufactured by Example 2, the inorganic filler has a different concentration gradient in a thickness direction of the insulating layer, and the plating adhesion is maintained, and the coefficient of thermal expansion property is improved, even without performing a roughening plating process of the primer layer on the insulating layer.

In addition, in the insulating films manufactured by the preferred embodiment of the present invention, the benzocyclobutene-based resin was used for the primer layer, and the primer layers of the insulating films manufactured by Examples 1 and 2 have a thickness in a range of 1 μm to 3 μm, such that the plating adhesion with the copper clad layer may be maintained without performing the desmear process. Meanwhile, in the insulating films manufactured by Comparative Examples 1 and 2, the desmear process is performed on the existing primer layer to form the plating adhesion.

In other words, when comparing Examples and Comparative Example 2, the benzocyclobutene-based resin according to the preferred embodiment of the present invention was used for the primer layer, such that the plating adhesion between the copper clad layer and the primer layer may be improved without performing the desmear process. In addition, it was measured that the insulating films manufactured by Examples had the plating adhesion of 0.5 kgf/cm or more, which is higher than that of the insulating film manufactured by Comparative Example 2.

Meanwhile, when comparing Examples and Comparative Example 1, the primer layer according to the prior art should be formed in a thickness of 3 μm or more due to the desmear process. The reason that measurement of the plating adhesion of the insulating film manufactured by Comparative Example 1 is not possible as shown in Table 1 above is that the inorganic filler is exposed on the surface of the insulating film during the desmear process and the exposed inorganic filler deteriorates the plating adhesion with the copper clad layer.

Therefore, since the desmear process is omitted, the process is simplified, and the deterioration in the plating adhesion occurring when the inorganic filler is exposed during the desmear process is not generated, such that the insulating films manufactured by Examples according to the preferred embodiment of the present invention may have a thickness less than 3 μm. That is, the thickness of the insulating film may be decreased.

In addition, in the insulating film manufactured by Comparative Example 1, the plating adhesion is deteriorated by the inorganic filler exposed during the desmear process, such that the content in the inorganic filler has a limitation. However, in the insulating films manufactured by Examples according to the preferred embodiment of the present invention, the desmear process is not performed, such that the content in the inorganic filler may be increased. In addition, due to the increased inorganic filler, the coefficient of thermal expansion property may be improved. Therefore, since the exposed inorganic filler causing the deterioration in the plating adhesion is not generated, the content in the inorganic filler may be increased to improve the coefficient of thermal expansion property.

As set forth above, the insulating film for the printed circuit board according to the preferred embodiment of the present invention, and the RCC, the FCCL, and the printed circuit board manufactured by using the same may have the low coefficient of thermal expansion and the high peel strength.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. An insulating film for a printed circuit board comprising:
an insulating layer; and
a primer layer formed on one surface of the insulating layer and including a benzocyclobutene (BCB)-based resin.

2. The insulating film as set forth in claim 1, wherein the insulating layer includes a liquid-crystal oligomer, an epoxy resin, and an inorganic filler, and the primer layer includes the benzocyclobutene (BCB)-based resin and the epoxy resin.

3. The insulating film as set forth in claim 2, wherein the insulating layer includes the liquid-crystal oligomer in an amount of 4 to 30 wt %, the epoxy resin in an amount of 5 to 30 wt %, and the inorganic filler in an amount of 40 to 90 wt %.

4. The insulating film as set forth in claim 2, wherein the primer layer includes the benzocyclobutene (BCB)-based resin in an amount of 50 to 80 wt % and the epoxy resin in an amount of 20 to 50 wt %.

5. The insulating film as set forth in claim 2, wherein the primer layer includes the benzocyclobutene (BCB)-based resin in an amount of 60 to 70 wt % and the epoxy resin in an amount of 30 to 40 wt %.

6. The insulating film as set forth in claim 2, wherein the epoxy resin included in the insulating layer or the primer layer is at least one selected from a group consisting of a naphthalene-based epoxy resin, a bisphenol A type epoxy resin, a phenol novolak epoxy resin, a cresol novolak epoxy resin, a rubber-modified epoxy resin, a phosphorus-based epoxy resin and a bisphenol F type epoxy resin.

7. The insulating film as set forth in claim 2, wherein the inorganic filler is at least one selected from a group consisting of silica (SiO₂), alumina (Al₂O₃), silicon carbide (SiC), barium sulfate (BaSO₄), talc, clay, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), calcium zirconate (CaZrO₃), and a combination thereof.

8. The insulating film as set forth in claim 2, wherein the inorganic filler included in the insulating layer has a concentration gradient in a thickness of the insulating layer, and has a higher concentration distribution in a region distant from the primer layer than in a region adjacent to the primer layer in the insulating layer.

9. The insulating film as set forth in claim 1, wherein the primer layer has a thickness in a range of 1 μm to 3 μm.

10. The insulating film as set forth in claim 2, wherein the insulating layer or the primer layer further includes a curing agent, a curing accelerator, or a combination thereof.

11. The insulating film as set forth in claim 10, wherein the curing agent is at least one selected from a group consisting of an amine-based curing agent, an acid anhydride-based curing agent, a polyamine curing agent, a polysulfide curing agent, a phenol novolak type curing agent, a bisphenol A type curing agent and a dicyandiamide curing agent.

12. The insulating film as set forth in claim 10, wherein the curing accelerator is at least one selected from a group consisting of a metal-based curing accelerator, an imidazole-based curing accelerator, and an amine-based curing accelerator.

13. The insulating film as set forth in claim 1, wherein the primer layer is formed by directly applying a primer solution on the insulating layer or casting the primer solution on a carrier film and then laminating and transferring the primer solution on the insulating layer.

14. A resin coated copper (RCC) or a flexible copper clad laminate (FCCL) manufactured by stacking and laminating copper clad layers on the primer layer of the insulating film for a printed circuit board as set forth in claim 1.

15. A printed circuit board manufactured by stacking and laminating the resin coated copper (RCC) or the flexible copper clad laminate (FCCL) as set forth in claim 14 on a substrate having a circuit pattern formed therein.
